(19) United States
(12) Patent Application Publication
(10) Pub. No.: US 2026/0262218 A1
(43) Pub. Date: Sep. 3, 2026

(54) 3D STACKED SEMICONDUCTOR DEVICE AND MANUFACTURING METHOD THEREFOR AND ELECTRONIC DEVICE

(71) Applicant: BEIJING SUPERSTRING ACADEMY OF MEMORY TECHNOLOGY, Beijing (CN)

(72) Inventors: Xuezheng Ai, Beijing (CN); Xiangsheng Wang, Beijing (CN); Guilei Wang, Beijing (CN); Jin Dai, Beijing (CN); Chao Zhao, Beijing (CN); Wenhua Gui, Beijing (CN)

(73) Assignee: BEIJING SUPERSTRING ACADEMY OF MEMORY TECHNOLOGY, Beijing (CN)

(21) Appl. No.: 19/159,902

(22) PCT Filed: Jun. 9, 2023
(86) PCT No.: PCT/CN2023/099466

§ 371 Date: Aug. 26, 2025

(30) Foreign Application Priority Data
Mar. 23, 2023 (CN) 202310292039.4

(51) Int. Cl. H10B 12/00; H10D 1/68

(52) U.S. Cl. CPC H10B 12/482; H10B 12/03; H10B 12/05; H10B 12/488; H10D 1/714

(57) ABSTRACT

The manufacturing method comprises: Sequentially and alternatively depositing a first insulating layer and a sacrificial layer on a substrate to obtain a stacked structure; etching the stacked structure, forming in the stacked structure a plurality of through holes extending towards the substrate, and depositing a second insulating layer in the through holes; performing patterning etching on the stacked structure provided with the through holes to obtain a patterned sacrificial layer, the patterned sacrificial layer comprising a plurality of bit line regions and a plurality of electrode regions each distributed between any two adjacent bit line regions; and replacing the patterned sacrificial layer with a patterned conduction layer, the patterned conduction layer comprising a plurality of bit lines extending in a first direction and a plurality of electrodes distributed on two sides of the bit lines and connected to the bit lines.

### CROSS-REFERENCE TO RELATED APPLICATIONS

The present application is a U.S. National Phase Entry of International Application PCT/CN2023/099466 having an international filing date of Jun. 9, 2023, which claims priority to Chinese Patent Application No. 202310292039.4 filed to the CNIPA on Mar. 23, 2023 and entitled “3D Stacked Semiconductor Device and Manufacturing Method Thereof, and Electronic Device”, and the contents disclosed in the above-mentioned applications are hereby incorporated as a part of this application.

### TECHNICAL FIELD

Embodiments of the present disclosure relate to, but are not limited to, the field of semiconductor devices, in particular to a 3D stacked semiconductor device, a manufacturing method therefor, and an electronic equipment.

### BACKGROUND

With the development of Dynamic Random Access Memory (DRAM) technology, in order to obtain higher integration, DRAM memory is gradually developing to three-dimensional (3D) structure. 3D dynamic random access memory has become an important direction of DRAM development in the future because of its storage density increased by several times.

### SUMMARY

The following is a summary of subject matter described in detail in this document. This summary is not intended to limit the scope of protection of the present disclosure.

Embodiments of the present disclosure provide a manufacturing method of a 3D stacked semiconductor device, the 3D stacked semiconductor device including: a word line, bit lines, and different layers of memory cells stacked and distributed in a direction perpendicular to a substrate, each layer including a plurality of columns of memory cells, and each memory cell including a transistor; the word line penetrates through the different layers of memory cells; and the bit lines extend along a first direction parallel to the substrate;

the manufacturing method includes:

alternately depositing a first insulating layer and a sacrificial layer on a substrate sequentially to obtain a stacked structure;

etching the stacked structure, forming a plurality of through holes extending toward the substrate in the stacked structure, and depositing a second insulating layer within the through holes;

performing patterned etching on the stacked structure with the through holes to obtain a patterned sacrificial layer including a plurality of bit line regions and a plurality of electrode regions distributed between any two adjacent bit line regions; and

replacing the patterned sacrificial layer with a conductive layer including a plurality of bit lines extending along the first direction and a plurality of electrodes distributed on two sides of the bit lines and connected to the bit lines.

In an exemplary embodiment of the present disclosure, the performing patterned etching on the stacked structure with the through holes to obtain the patterned sacrificial layer may include:

performing patterned etching on the stacked structure with the through holes to form a plurality of first grooves extending toward the substrate in the stacked structure, wherein the first grooves extend in a second direction parallel to the substrate and are located between two adjacent through holes distributed in the first direction, to obtain the patterned sacrificial layer.

In an exemplary embodiment of the present disclosure, the performing patterned etching on the stacked structure with the through holes to obtain the patterned sacrificial layer may further include:

performing patterned etching on the stacked structure with the through holes, to form a plurality of second grooves extending toward the substrate in the stacked structure, wherein the second grooves extend along the first direction and are located between any two adjacent bit line regions to obtain an electrode region having only one end connected to a bit line region through a transistor.

In an exemplary embodiment of the present disclosure, the replacing the patterned sacrificial layer with the conductive layer may include:

removing all of patterned sacrificial layers between the first insulating layers by etching;

filling a conductive layer between a first groove and two adjacent first insulating layers; and

removing the conductive layer in the first groove by etching to obtain the patterned conductive layer, and replacing the patterned sacrificial layer with the patterned conductive layer.

In an exemplary embodiment of the present disclosure, the memory cell may further include a capacitor including a third electrode, a fourth electrode, and a dielectric layer disposed between the third electrode and the fourth electrode;

the manufacturing method may further include, after replacing the patterned sacrificial layer with the conductive layer, performing the following steps of:

laterally etching the first insulating layers on two sides of the second groove until side surfaces of a set depth of the electrode are exposed, with the set depth being a length of the third electrode of the capacitor; and

forming the dielectric layer and the fourth electrode of the capacitor sequentially in an exposed region of the electrode.

In an exemplary embodiment of the present disclosure, the manufacturing method may further include, before or after forming the capacitor, performing the following steps:

removing the second insulating layer in a through hole by etching, and sequentially depositing a semiconductor layer and a gate insulating layer on an inner wall of the through hole, and filling the through hole with a gate electrode layer;

removing the first insulating layer by etching to expose a semiconductor layer in a parasitic Metal-Oxide-Semiconductor (MOS) region originally surrounded by the first insulating layer;

removing the semiconductor layer located in the parasitic MOS region by etching, with a gate electrode layer surrounded by the semiconductor layer located in a channel region being used as a gate electrode, and gate electrodes of transistors of a column of memory cells located in different layers being connected to form the word line.

In an exemplary embodiment of the present disclosure, the manufacturing method may further include, after obtaining the gate electrode, performing the following steps:

removing a conductive layer on opposite sidewalls of the semiconductor layer by etching such that an end of the electrode close to the bit line is spaced apart as a first electrode and a second electrode.

In an exemplary embodiment of the present disclosure, the sacrificial layer does not contain a metallic element.

In an exemplary embodiment of the present disclosure, both the first insulating layer and the sacrificial layer contain a silicon element.

In an exemplary embodiment of the present disclosure, a material of the first insulating layer is silicon oxide, and a material of the sacrificial layer is silicon nitride or polysilicon.

Embodiments of the present disclosure also provide a 3D stacked semiconductor device, the 3D stacked semiconductor device including:

a plurality of memory cells distributed in different layers stacked along a direction perpendicular to a substrate and periodically distributed; wherein each layer includes a plurality of columns of memory cells, and a memory cell includes a transistor; the transistor includes a first electrode, a second electrode, a gate electrode, a semiconductor layer surrounding a sidewall of the gate electrode, and a gate insulating layer disposed between the sidewall of the gate electrode and the semiconductor layer, the semiconductor layer connects the first electrode with the second electrode; and the gate electrode extend along a direction perpendicular to the substrate;

a plurality of bit lines extending along a first direction parallel to the substrate, and transistors of two columns of memory cells located on a same layer and adjacent in a second direction parallel to the substrate are connected to a same bit line;

the bit line located on a same layer is located on a same conductive layer as the first electrode and the second electrode of the transistor; and

the conductive layer is obtained by replacing and patterning a sacrificial layer in a stacked structure formed by alternately stacking a first insulating layer and a sacrificial layer.

In an exemplary embodiment of the present disclosure, the 3D stacked semiconductor device may further include a word line extending along the direction perpendicular to the substrate, a third insulating layer positioned between two adjacent conductive layers, the word lines being positioned in a through hole penetrating various third insulating layers and various conductive layers;

wherein the through hole is formed by a single process.

The semiconductor layer is formed only at an end portion of the conductive layer and does not extend to upper and lower surfaces of the conductive layer.

In an exemplary embodiment of the present disclosure, the semiconductor layer extends only along the direction perpendicular to the substrate and does not include a region extending along the first direction.

In an exemplary embodiment of the present disclosure, the memory cell may further include:

a capacitor connected to the transistor;

the capacitor includes a third electrode on the conductive layer, wherein third electrodes of capacitors of the plurality of memory cells distributed by stacking extend in the second direction; cross-sectional shapes of the third electrodes at a same position are the same, and cross sections of the third electrodes at different positions gradually increase along a direction close to the transistor.

In an exemplary embodiment of the present disclosure, the capacitor may further include a fourth electrode and a dielectric layer disposed between the third electrode and the fourth electrode;

wherein the third insulating layer, the gate insulating layer, and the dielectric layer are made of a same material and are all made of silicon oxide.

In an exemplary embodiment of the present disclosure, a cross section of the third electrode is larger than a cross section of the first electrode to which a bit line is connected.

Embodiments of the present disclosure further provide an electronic equipment including the 3D stacked semiconductor device as provided in the above embodiments of the present disclosure.

Other aspects may be understood upon reading and understanding the drawings and detailed description.

### BRIEF DESCRIPTION OF DRAWINGS

Accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1 is a process flowchart of a manufacturing method of a 3D stacked semiconductor device according to an exemplary embodiment of the present disclosure.

FIG. 2A is a schematic diagram of a three-dimensional structure after a stacked structure is formed using a manufacturing method of a 3D stacked semiconductor device according to an exemplary embodiment of the present disclosure.

FIG. 2B is a cross-sectional view of the structure shown in FIG. 2A on a C1 plane parallel to a substrate.

FIG. 2C is a cross-sectional view of the structure shown in FIG. 2A on a C2 plane perpendicular to the substrate.

FIG. 3A is a cross-sectional view after a through hole of a 3D stacked semiconductor device is formed by using a manufacturing method on a C1 plane parallel to a substrate according to an exemplary embodiment of the present disclosure.

FIG. 3B is a cross-sectional view of the structure shown in FIG. 3A on a C2 plane parallel to the substrate.

FIG. 3C is a cross-sectional view of the structure shown in FIG. 3A on a C3 plane perpendicular to the substrate.

FIG. 4A is a cross-sectional view after a second insulating layer is filled in a through hole of a 3D stacked semiconductor device by using a manufacturing method on a C1 plane parallel to a substrate according to an exemplary embodiment of the present disclosure.

FIG. 4B is a cross-sectional view of the structure shown in FIG. 4A on a C2 plane parallel to the substrate.

FIG. 4C is a cross-sectional view of the structure shown in FIG. 4A on a C3 plane perpendicular to the substrate.

FIG. 5A is a cross-sectional view after a first groove of a 3D stacked semiconductor device is formed by using a manufacturing method on a C1 plane parallel to a substrate according to an exemplary embodiment of the present disclosure.

FIG. 5B is a cross-sectional view of the structure shown in FIG. 5A on a C2 plane parallel to the substrate.

FIG. 5C is a cross-sectional view of the structure shown in FIG. 5A on a C3 plane perpendicular to the substrate.

FIG. 6A is a cross-sectional view after a sacrificial layer of a 3D stacked semiconductor device is removed by using a manufacturing method on a C1 plane parallel to a substrate according to an exemplary embodiment of the present disclosure.

FIG. 6B is a cross-sectional view of the structure shown in FIG. 6A on a C2 plane parallel to the substrate.

FIG. 6C is a cross-sectional view of the structure shown in FIG. 6A on a C3 plane perpendicular to the substrate.

FIG. 7A is a cross-sectional view after a conductive layer of a 3D stacked semiconductor device is formed by using a manufacturing method on a C1 plane parallel to a substrate according to an exemplary embodiment of the present disclosure.

FIG. 7B is a cross-sectional view of the structure shown in FIG. 7A on a C2 plane parallel to the substrate.

FIG. 7C is a cross-sectional view of the structure shown in FIG. 7A on a C3 plane perpendicular to the substrate.

FIG. 8A is a cross-sectional view after a patterned conductive layer of a 3D stacked semiconductor device is formed by using a manufacturing method on a C1 plane parallel to a substrate according to an exemplary embodiment of the present disclosure.

FIG. 8B is a cross-sectional view of the structure shown in FIG. 8A on a C2 plane parallel to the substrate.

FIG. 8C is a cross-sectional view of the structure shown in FIG. 8A on a C3 plane perpendicular to the substrate.

FIG. 9A is a cross-sectional view after a capacitor of a 3D stacked semiconductor device is formed by using a manufacturing method on a C1 plane parallel to a substrate according to an exemplary embodiment of the present disclosure.

FIG. 9B is a cross-sectional view of the structure shown in FIG. 9A on a C2 plane parallel to the substrate.

FIG. 9C is a cross-sectional view of the structure shown in FIG. 9A on a C3 plane perpendicular to the substrate.

FIG. 10A is a cross-sectional view after a gate electrode thin film of a 3D stacked semiconductor device is formed by using a manufacturing method on a C1 plane parallel to the substrate according to an exemplary embodiment of the present disclosure.

FIG. 10B is a cross-sectional view of the structure shown in FIG. 10A on a C2 plane perpendicular to the substrate.

FIG. 10C is a cross-sectional view of the structure shown in FIG. 10A on a C3 plane perpendicular to the substrate.

FIG. 11A is a cross-sectional view after a first insulating layer of a 3D stacked semiconductor device is removed by using a manufacturing method on a C1 plane parallel to the substrate according to an exemplary embodiment of the present disclosure.

FIG. 11B is a cross-sectional view of the structure shown in FIG. 11A on a C2 plane perpendicular to the substrate.

FIG. 11C is a cross-sectional view of the structure shown in FIG. 11A on a C3 plane perpendicular to the substrate.

FIG. 12A is a cross-sectional view of a 3D stacked semiconductor device obtained by using a manufacturing method of the 3D stacked semiconductor device on a C1 plane parallel to a substrate according to an exemplary embodiment of the present disclosure.

FIG. 12B is a cross-sectional view of the device shown in FIG. 12A on a C2 plane perpendicular to the substrate.

FIG. 12C is a cross-sectional view of the device shown in FIG. 12A on a C3 plane perpendicular to the substrate.

### DETAILED DESCRIPTION

To make the objectives, technical solutions, and advantages of the present disclosure clearer, the embodiments of the present disclosure will be described in detail below in combination with the accompany drawings. It should be noted that the embodiments of the present disclosure and the features of the embodiments may be arbitrarily combined with each other if there is no conflict.

An implementation of the present disclosure is not necessarily limited to dimensions shown in the drawings, and the shapes and sizes of the components in the drawings do not reflect actual scales. Further, the drawings schematically illustrate ideal examples, but embodiments of the present disclosure are not limited to shapes or values shown in the drawings.

Ordinal numerals such as “first” and “second” in the present disclosure are provided to avoid confusion of constituent elements, but do not indicate any order, quantity or importance.

In the present disclosure, for convenience, words or expressions indicating orientation or positional relationship such as “middle”, “upper”, “lower”, “front”, “rear”, “vertical”, “horizontal”, “top”, “bottom”, “inner” and “outer” are employed to explain positional relationship of the constituent elements with reference to the accompanying drawings, they are employed for ease of description of the specification and simplification of the description only, but do not indicate or imply that the referred device or element must have a particular orientation and be constructed and operate in a particular orientation, and therefore cannot be construed as limitations on the present disclosure. The positional relationship of the constituent elements is appropriately changed according to a direction in which various constituent elements are described. Therefore, the present disclose is not limited to the words or expressions described in the present disclosure, and replacement may be appropriately made according to the situation.

In the present disclosure, terms “mount”, “couple” and “connect” should be understood broadly, unless otherwise expressly specified and defined. For example, it may be a fixed connection, a detachable connection, or an integral connection; it may be a mechanical connection or an electrical connection; it may be a direct connection, an indirect connection through a middleware, or an internal communication between two elements. For those of ordinary skills in the art, specific meanings of the above terms in the present disclosure may be understood according to actual situations.

In the present disclosure, a transistor refers to an element including at least three terminals, i.e., a gate electrode, a drain electrode, and a source electrode. A transistor has a channel region between a drain electrode (drain electrode terminal, drain region, or drain) and a source electrode (source electrode terminal, source region, or source), and a current can flow through the drain electrode, the channel region, and the source electrode. In the present disclosure, the channel region refers to the region through which the current mainly flows.

In the present disclosure, the first electrode may be a drain electrode and the second electrode may be a source electrode, or the first electrode may be a source electrode and the second electrode may be a drain electrode. In cases that transistors with opposite polarities are used, or a current direction changes during work of a circuit, or the like, functions of the “source electrode” and the “drain electrode” may sometimes be exchanged. Therefore, in the present disclosure, the “source electrode” and the “drain electrode” are interchangeable.

In the present disclosure, “electrical connection” includes the case where the constituent elements are connected together by elements having certain electrical effects. There is no special restriction on “elements with certain electrical effects” as long as they can transmit and receive electrical signals between connected constituent elements. Examples of “elements having certain electrical effects” include not only electrodes and wirings, but also switching elements (such as transistors), resistors, inductors, capacitors, and other elements having various functions, etc.

In the present disclosure, “parallel” refers to approximately parallel or almost parallel, for example, a state in which the angle formed by two straight lines is −10 degrees or more and 10 degrees or less, and therefore further includes a state in which the angle is −5 degrees or more and 5 degrees or less. In addition, “perpendicular” refers to “approximately perpendicular”, for example, a state in which the angle formed by two straight lines is 80 degrees or more and 100 degrees or less, and therefore further includes a state in which the angle is 85 degrees or more and 95 degrees or less.

In the present disclosure, “film” and “layer” may be interchanged with each other. For example, “conductive layer” may sometimes be replaced by “conductive film”. Similarly, “insulating film” may sometimes be replaced by “insulating layer”.

In the present disclosure, “A and B being arranged in a same layer” means that A and B are simultaneously formed by a same patterning process.

“A and B being of an integrated structure” in embodiments of the present disclosure may mean that there is no obvious boundary interface, such as obvious faultage or gaps, viewed from the microstructure. Generally, connected film layers formed by patterning on one film layer are of an integrated structure. For example, A and B form one film layer using a same material and simultaneously form a structure with a connection relationship through a same patterning process.

With the continuous development of 3D DRAM, choices of channel materials have become more extensive, breaking through the limitation that only single crystal silicon can be used as channel material. A metal oxide may be used as the channel material, and a fabrication process of 3D DRAM may not employ a silicon epitaxy process compared with single crystal silicon as the channel material.

Regardless of whether the channel material is metal oxide or silicon, for 3D stacked devices, one implementation mode is to deposit alternately stacked layers of metal-containing conductive layer/dielectric layer and etch word line (WL) holes in the stacked layers. Because of the quite large difference in characteristics of materials of the metal-containing conductive layer and the dielectric layer are very different, film deposition of metal and dielectric layer cannot be completed in a same machine, and switching of machines leads to an increase in process cost. In addition, when etching deep holes in a stacked structure of metal-containing conductive layer/dielectric layer, the sidewall morphology is not easy to control due to the relatively large difference in material characteristics, especially when etching through holes with small size, which poses a greater challenge to the etching process.

An embodiment of the present disclosure provides a manufacturing method of a 3D stacked semiconductor device. When a plurality of film layers are stacked in a first step, two film layers having similar properties are stacked. For example, a film layer containing silicon is stacked instead of a metal-containing film layer, such as a metal or conductive layer such as Titanium (Ti), Titanium Nitride (TIN), Tungsten (W), etc. For example, after the basic structure of BL and transistor electrodes is prepared on the stacked film layer by alternate stacking of silicon oxide and silicon nitride or polysilicon, the silicon nitride or polysilicon as the sacrificial layer is replaced with a metal layer or a metal-containing conductive layer to replace the sacrificial layer with a metal-containing BL and transistor electrodes. After preparing a bit line (BL) and an electrode, the WL is prepared.

The WL may be fabricated before the silicon nitride or polysilicon is replaced with the metal layer, or may be fabricated after the silicon nitride or polysilicon is replaced with the metal layer.

In addition, when the conductive layer is replaced, a single layer may be formed or two layers may be formed successively, for example, TiN and Ti or W are formed, and TiN plays a protective role for a main conductive layer (Ti or W) and prevents SiO from oxidizing the main conductive layer.

Hereinafter, the present application will be illustrated by stacking and patterning silicon oxide and polysilicon as an example.

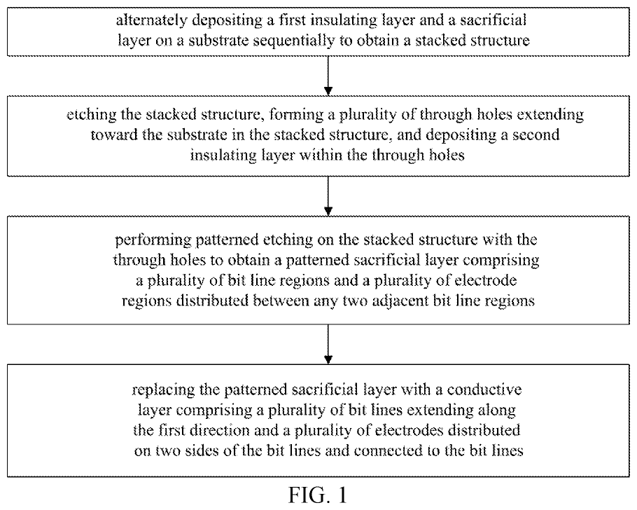

FIG. 1 is a process flowchart of a manufacturing method of a 3D stacked semiconductor device according to an exemplary embodiment of the present disclosure.

Embodiments of the present disclosure provide a manufacturing method of a 3D stacked semiconductor device. The 3D stacked semiconductor device includes: a word line, a bit line, and different layers of memory cells stacked and distributed in a direction perpendicular to a substrate. Each layer includes a plurality of columns of memory cells, and each memory cell includes a transistor. The word line runs through the different layers of memory cells. The bit lines extend along a first direction parallel to the substrate;

As shown in FIG. 1, the manufacturing method of a 3D stacked semiconductor device includes:

alternately depositing a first insulating layer and a sacrificial layer on a substrate sequentially to obtain a stacked structure;

etching the stacked structure, forming a plurality of through holes extending toward the substrate in the stacked structure, depositing a second insulating layer within the through holes;

performing patterned etching on the stacked structure with through holes to obtain a patterned sacrificial layer including a plurality of bit line regions and a plurality of electrode regions distributed between any two adjacent bit line regions;

replacing the patterned sacrificial layer with a conductive layer including a plurality of bit lines extending along a first direction and a plurality of electrodes distributed on two sides of the bit lines and connected to the bit lines.

In the manufacturing method of the 3D stacked semiconductor device according to the embodiment of the present disclosure, a stacked structure of a first insulating layer and a sacrificial layer is firstly deposited, then patterned etching is performed on the stacked structure according to shapes of a desired bit line and source electrode and drain electrode of a transistor, and then the patterned sacrificial layer is replaced by a conductive layer, thereby forming the bit line and the source electrode and the drain electrode of the transistor. In this method, the deposition and etching processes of the insulating layer and the sacrificial layer are relatively mature, and the morphology of the through hole and groove formed by etching is easy to control, thus reducing the process difficulty of device manufacturing.

In an exemplary embodiment of the present disclosure, performing patterned etching on the on the stacked structure with through holes to obtain the patterned sacrificial layer may include:

performing patterned etching on the stacked structure with through holes to form a plurality of first grooves extending toward the substrate in the stacked structure, wherein the first grooves extend in a second direction parallel to the substrate and are located between two adjacent through holes distributed in the first direction, so as to obtain the patterned sacrificial layer.

In an exemplary embodiment of the present disclosure, performing patterned etching on the stacked structure with through holes to obtain the patterned sacrificial layer may further include:

performing patterned etching on the stacked structure with through holes, to form a plurality of second grooves extending toward the substrate in the stacked structure, wherein the second grooves extend along the first direction and are located between any two adjacent bit line regions to obtain an electrode region having only one end connected to a bit line region through a transistor.

In an exemplary embodiment of the present disclosure, replacing the patterned conductive layer with the patterned sacrificial layer may include:

removing all of patterned sacrificial layers between the first insulating layers by etching;

filling a conductive layer between a first groove and two adjacent first insulating layers;

removing the conductive layer in the first groove by etching to obtain the patterned conductive layer, and replacing the patterned sacrificial layer with the patterned conductive layer.

In an exemplary embodiment of the present disclosure, each transistor may be one of transistors in one memory cell, such as a transistor in a memory cell having a 1T1C structure, or a write transistor in a memory cell having a 2TOC structure.

In an exemplary embodiment of the present disclosure, the memory cell may further include a capacitor including a third electrode, a fourth electrode, and a dielectric layer disposed between the third electrode and the fourth electrode;

The manufacturing method may further include, after replacing the patterned sacrificial layer with the conductive layer, performing the following steps:

laterally etching the first insulating layers on two sides of the second groove until side surfaces of a set depth of the electrode are exposed, with the set depth being a length of the third electrode of the capacitor;

forming the dielectric layer and the fourth electrode of the capacitor sequentially in an exposed region of the electrode.

In an exemplary embodiment of the present disclosure, the manufacturing method may further include, before or after forming the capacitor, performing the following steps:

removing the second insulating layer in a through hole by etching, and sequentially depositing a semiconductor layer and a gate insulating layer on an inner wall of the through hole, and filling the through hole with a gate electrode layer;

removing the first insulating layer by etching to expose a semiconductor layer in a parasitic Metal-Oxide-Semiconductor (MOS) region originally surrounded by the first insulating layer;

removing the semiconductor layer located in the parasitic MOS region by etching, a gate electrode layer surrounded by the semiconductor layer located in the channel region being used as a gate electrode, and gate electrodes of transistors of a column of memory cells located in different layers being connected to form a word line.

In the description of the present disclosure, two adjacent conductive layers and a semiconductor layer between the two conductive layers constitute a parasitic MOS, and the “semiconductor layer in a parasitic MOS region” means the semiconductor layer between the two adjacent conductive layers.

In an exemplary embodiment of the present disclosure, the manufacturing method may further include, after obtaining the gate electrode, performing the following steps:

removing a conductive layer on opposite sidewalls of the semiconductor layer by etching such that an end of the electrode close to a bit line is spaced apart as a first electrode and a second electrode.

In an exemplary embodiment of the present disclosure, the sacrificial layer does not contain a metallic element.

In an exemplary embodiment of the present disclosure, both the first insulating layer and the sacrificial layer contain a silicon element.

In an exemplary embodiment of the present disclosure, a material of the first insulating layer is silicon oxide, and a material of the sacrificial layer is silicon nitride or polysilicon.

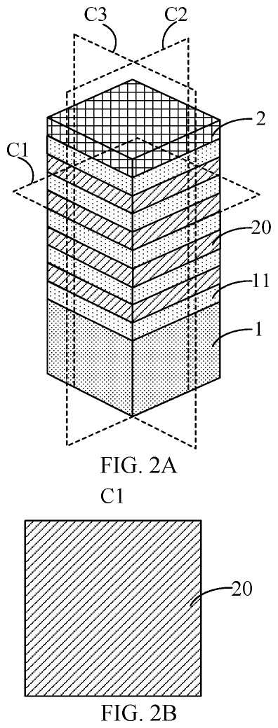

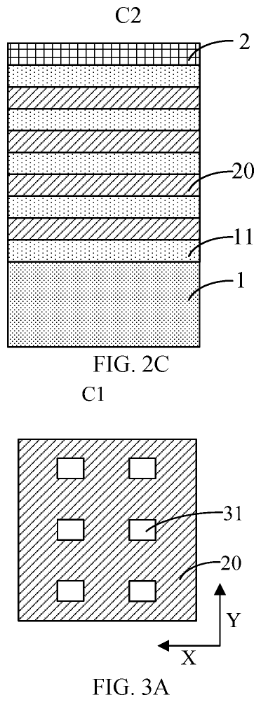

As shown in FIGS. 2A to 12C, in an exemplary embodiment, the manufacturing method of the 3D stacked semiconductor device may include:

S101: providing a substrate 1, and alternately depositing a first insulating layer 11 and a sacrificial layer 20 on the substrate 1 to obtain a stacked structure composed of the first insulating layer 11 and the sacrificial layer 20 which are distributed by stacking; depositing a Hard Mask (HM) 2 on a top surface of the stacked structure, as shown in FIGS. 2A, 2B, and 2C.

Here, FIG. 2B is a cross-sectional view on a C1 plane parallel to the substrate, and the C1 plane passes through the sacrificial layer. FIG. 2C is a cross-sectional view on a C2 plane perpendicular to the substrate, a C3 plane is a cross-sectional view perpendicular to the substrate, the C3 plane is perpendicular to the C2 plane, a cross-sectional view of the structure shown in FIG. 2A on the C3 plane is similar to that of FIG. 2C. Positions of the C1 plane, the C2 plane, and the C3 plane may be as shown in FIG. 2A, and directions of the C1 plane, the C2 plane, and the C3 plane hereinafter are the same as the directions of the C1 plane, the C2 plane, and the C3 plane in FIG. 2A, but the cutting plane locations may be different.

In an exemplary embodiment of the present disclosure, the substrate may be a semiconductor substrate, which may be, for example, a silicon substrate.

In an exemplary embodiment of the present disclosure, the material forming the first insulating layer may be a low-K dielectric material, that is, a dielectric material having a dielectric constant K<3.9, including but not limited to a silicon oxide, such as silicon dioxide (SiO2) or other film layers containing silicon, and the like.

In exemplary embodiments of the present disclosure, the material of the sacrificial layer includes, but is not limited to, at least one of polysilicon, silicon nitride (SiN), or other silicon-containing film layers.

In one embodiment, the substrate may be silicon, and the silicon oxide and polycrystalline silicon may be epitaxially grown on the substrate when being stacked, which may be achieved in a cavity corresponding to a deposition or epitaxial process, and the process is simpler.

The stacked structure shown in FIG. 2A includes five layers of first insulating layers 11 and four layers of sacrificial layers 20, which is only an example. In some other embodiments, the stacked structure may include more or fewer layers of the first insulating layers 11 and the sacrificial layers 20 that are alternately arranged.

S102: etching the stacked structure to form a plurality of through holes 31 extending toward the substrate 1 in the stacked structure, with the plurality of through holes 31 in each layer being distributed at intervals in a second direction parallel to the substrate 1 and a first direction parallel to the substrate 1.

The first insulating layers and the sacrificial layers in the stacked structure are film layers with similar properties, for example, film layers containing silicon, such as silicon oxide, silicon nitride or polysilicon, instead of a metal or conductive layer such as Ti, TIN, W, etc. With film layer containing silicon, such as silicon oxide, silicon nitride or polysilicon, on the one hand, it is easy to control the morphology of inner wall of a through hole or a groove during subsequently etching for forming a through hole such as a WL hole or a groove, and reduces the process difficulty. Moreover, the etching can be performed using a same machine, thereby reducing the process cost.

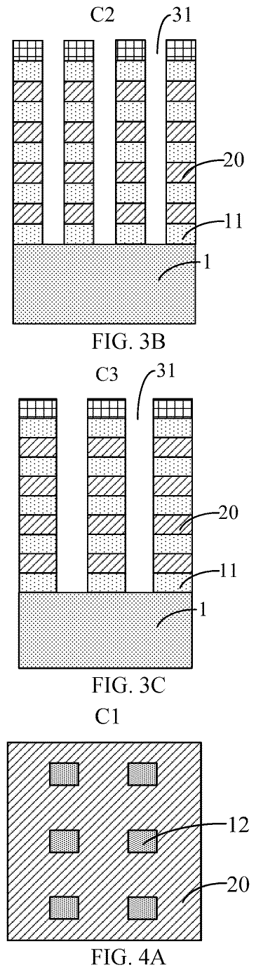

For example, a forming process of through holes 31 may include the following steps: forming a photoresist pattern on a surface of the hard mask 2 by photolithography; etching the hard mask 2 using the photoresist pattern as a mask to obtain a patterned hard mask 2, etching (i.e. patterned etching) the stacked structure using the patterned hard mask 2 as a mask to form a plurality of through holes 31 extending toward the substrate 1 in the stacked structure, and removing the photoresist pattern, as shown in FIGS. 3A, 3B, and 3C. Here, FIG. 3A is a cross-sectional view on a C1 plane parallel to the substrate, and the C1 plane passes through the sacrificial layer. FIG. 3B is a cross-sectional view on a C2 plane perpendicular to the substrate, and the C2 plane passes through the through holes. FIG. 3C is a cross-sectional view on a C3 plane perpendicular to the substrate, and the C3 plane passes through the through holes.

For example, an extension direction of the through holes 31 may be perpendicular to the substrate 1, and the through holes 31 may penetrate each sacrificial layer 20, and may penetrate each first insulating layer 11.

The second direction may be the X direction as shown in FIG. 3A, the first direction may be the Y direction as shown in FIG. 3A, and the second direction and the first direction may be perpendicular to each other.

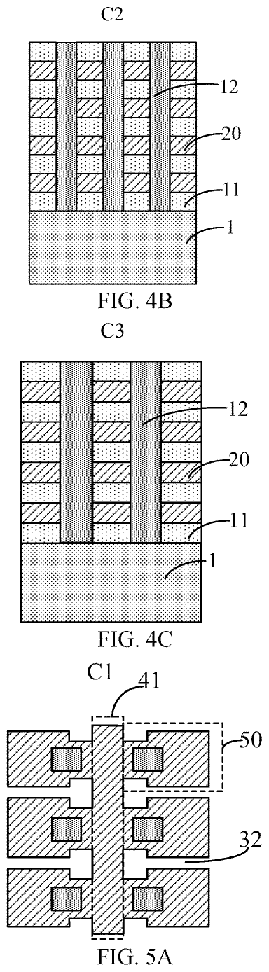

S103: filling the through holes 31 with the second insulating layer 12, and removing excess insulating material on the surface of the structure by a Chemical Mechanical Polishing (CMP) process to achieve planarization, as shown in FIGS. 4A, 4B, and 4C. Here, FIG. 4A is a cross-sectional view on a C1 plane parallel to the substrate, and the C1 plane passes through the sacrificial layer. FIG. 4B is a cross-sectional view on a C2 plane perpendicular to the substrate, and the C2 plane passes through the second insulating layer. FIG. 4C is a cross-sectional view on a C3 plane perpendicular to the substrate, and the C3 plane passes through the second insulating layer.

In an exemplary embodiment of the present disclosure, the material forming the second insulating layer includes, but is not limited to, an oxide silicon, a nitride of silicon, for example, silicon nitride, or the like. However, materials of the first insulating layer and the second insulating layer are different as long as the first insulating layers are not etched when the second insulating layer is subsequently etched.

Step S103 may further include: removing the patterned hard mask 2 on the surface of the structure by a CMP process. Evidently, the patterned hard mask 2 on the surface of the structure can also be retained.

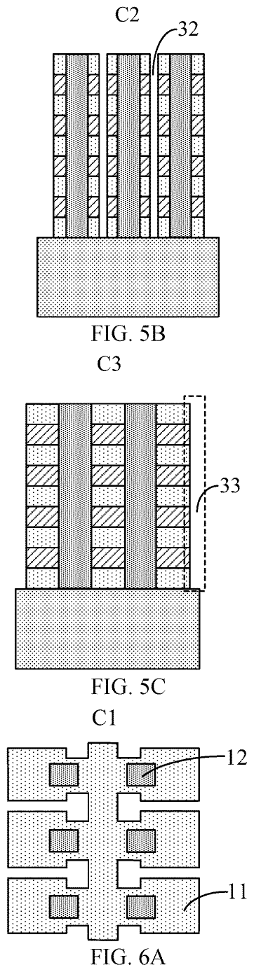

S104: performing patterned etching on the stacked structure filled with the second insulating layer, to form a plurality of first grooves 32 extending toward the substrate 1 in the stacked structure, wherein the first grooves 32 extend in the second direction and are located between two adjacent through holes 31 distributed in the first direction, and after the first grooves 32 are formed, the side walls of the through holes 31 located in the patterned sacrificial layer are surrounded by the patterned sacrificial layer. The patterned sacrificial layer 20 includes a plurality of bit line regions 41 extending along the first direction and a plurality of electrode regions 50 distributed between any two adjacent bit line regions 41, as shown in FIGS. 5A, 5B, and 5C. Here, FIG. 5A is a cross-sectional view on a C1 plane parallel to the substrate, and the C1 plane passes through the sacrificial layer. FIG. 5B is a cross-sectional view on a C2 plane perpendicular to the substrate, and the C2 plane passes through the second insulating layer and the first groove. FIG. 5C is a cross-sectional view on a C3 plane perpendicular to the substrate, and the C3 plane does not pass through the first groove. The C3 plane is perpendicular to the C2 plane.

For example, a first groove 32 may include a first end away from a bit line region 41 and a second end close to a bit line region 41, a cross section of the first end is smaller than a cross section of the second end, and the cross section here refers to a cross section perpendicular to the substrate 1 and extending in the first direction.

For example, cross sections at different positions of the first groove 32 gradually increase in a direction close to the bit line region 41, and a cross section here refers to a cross section perpendicular to the substrate 1 and extending in the first direction.

The larger cross section of one end close to the bit line region 41 is advantageous for subsequent etching of film layers close to the bit line region 41, for example, etching of the semiconductor layer in the parasitic MOS region and etching of the conductive layer in the channel region.

For example, step S104 may further include forming a plurality of second grooves 33 extending toward the substrate 1 in the stacked structure by etching, wherein the second grooves 33 extend along the first direction and are located between any two adjacent bit line regions 41, only one end of the obtained electrode region 50 is connected to a bit line region 41, an end surface of the other end of the electrode region 50 is exposed by a second groove 33, and electrode regions 50 respectively connected to the two adjacent bit line regions 41 are spaced apart by the second groove 33.

Optionally, in step S104, the second groove 33 may not be formed to obtain an initial electrode region having both ends connected to two adjacent bit line regions 41 at the same time, and then the second groove 33 may be etched to separate the initial electrode regions into two electrode regions.

For example, in step S104, the stacked structure filled with the second insulating layer may be subjected to patterned etching by photolithography and etching methods, and the operation process may refer to the process of etching the through holes in step S102.

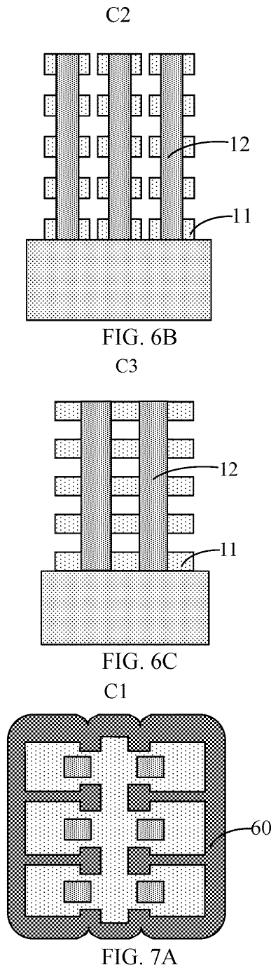

S105: removing all sacrificial layers 20 between adjacent first insulating layers by isotropic etching, as shown in FIGS. 6A, 6B, and 6C. Here, FIG. 6A is a cross-sectional view on a C1 plane parallel to the substrate, and the C1 plane passes through the first insulating layer. FIG. 6B is a cross-sectional view on a C2 plane perpendicular to the substrate, and the C2 plane passes through the second insulating layer and the first groove. FIG. 6C is a cross-sectional view on a C3 plane perpendicular to the substrate, and the C3 plane does not pass through the first groove.

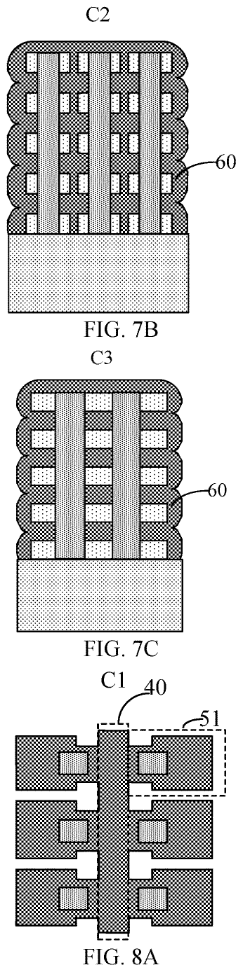

S106: filling the substrate 1 with a conductive layer 60 covering a gap between the first groove 32 and two adjacent first insulating layers 11, as shown in FIGS. 7A, 7B, and 7C. Here, FIG. 7A is a cross-sectional view on a C1 plane parallel to the substrate, and the C1 plane passes through the first insulating layer. FIG. 7B is a cross-sectional view on a C2 plane perpendicular to the substrate, and the C2 plane passes through the second insulating layer and the first groove. FIG. 7C is a cross-sectional view on a C3 plane perpendicular to the substrate, and the C3 plane does not pass through the first groove. Among them, the conductive layer 60 may be in a single layer structure or a multilayer structure, for example, a single layer structure formed of TiN, or a multilayer structure formed of TiN and W, where TiN acts as an oxidation resistant layer to prevent W from being oxidized by contact with an oxygen film layer.

For example, the conductive layer may include, but is not limited to, a multilayer structure of titanium nitride (TiN)/tungsten (W). The titanium nitride is provided between a first insulating layer and tungsten to prevent the tungsten from being oxidized under influence of the first insulating layer containing oxygen, and the film layer formed of the titanium nitride may be referred to as an oxidation prevention layer.

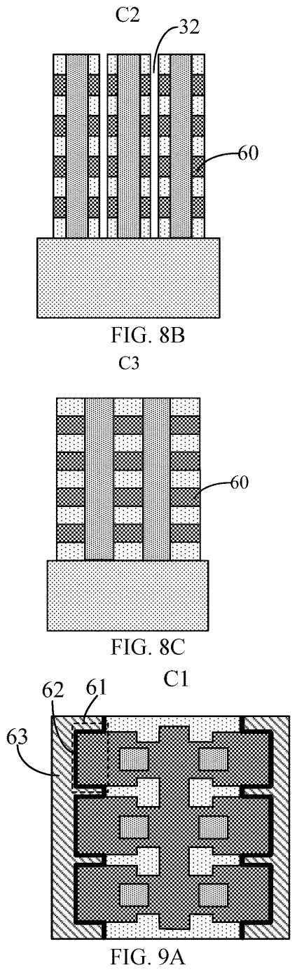

S107: performing patterned etching on the conductive layer 60 to obtain a patterned conductive layer having a same pattern as the patterned sacrificial layer obtained in step S104, including a bit line 40 formed in a bit line region 41 and an electrode 51 formed in an electrode region 50, wherein the bit line 40 extend along the first direction and has a same shape as the bit line region 41, and the electrode 51 is distributed (which may be a mirror image distribution) on two sides of the bit line 40 and has one end connected to the bit line 40, and the sidewall of the through hole 31 located in the patterned conductive layer is surrounded by the patterned sacrificial layer, as shown in FIGS. 8A, 8B, and 8C. Here, FIG. 8A is a cross-sectional view on a C1 plane parallel to the substrate, and the C1 plane passes through the patterned conductive layer. FIG. 8B is a cross-sectional view on a C2 plane perpendicular to the substrate, and the C2 plane passes through the second insulating layer and the first groove. FIG. 8C is a cross-sectional view on a C3 plane perpendicular to the substrate, and the C3 plane passes through the electrode.

For example, the patterned etching on the conductive layer 60 includes at least removal of the conductive layer within the first groove by etching. In some embodiments, the conductive layer between two adjacent first insulating layers is etched into the same or similar shape as the patterned sacrificial layer obtained in step S104.

For example, if the conductive layer has a double-layer structure of titanium nitride and tungsten, the titanium nitride layer may be patterned and etched first, and then the tungsten layer may be patterned and etched.

S108: forming a capacitor is formed at an end of the electrode 51 away from the bit line 40.

For example, the electrode 51 in a direction away from the bit line 40 may sequentially include a first electrode region, a second electrode region, and a third electrode region. The first electrode region and a second electrode region are subsequently used to form the first electrode and the second electrode of the transistor, and the third electrode region is used to form the third electrode 61 of the capacitor.

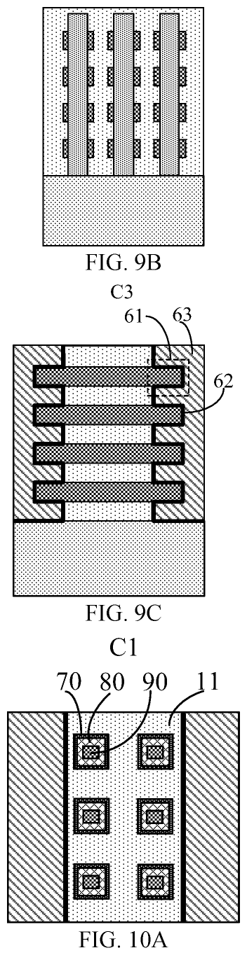

The forming the capacitor at the end of the electrode 51 away from the bit line 40 may include: etching the first insulating layer 11 on two sides of a second groove so that the third electrode region of the electrode 51 is exposed, forming a dielectric layer 62 and a fourth electrode 63 on a surface of the exposed third electrode region, using the third electrode region as the third electrode 61, and forming the capacitor with the dielectric layer 62 and the fourth electrode 63, as shown in FIGS. 9A, 9B, and 9C. Here, FIG. 9A is a cross-sectional view on a Cl plane parallel to the substrate, and the C1 plane passes through the patterned conductive layer. FIG. 9B is a cross-sectional view on a C2 plane perpendicular to the substrate, and the C2 plane passes through the second insulating layer and the first groove. FIG. 9C is a cross-sectional view on a C3 plane perpendicular to the substrate, and the C3 plane passes through the electrode.

In an exemplary embodiment, the forming the capacitor at the end of the electrode 51 away from the bit line 40 may include:
1) filling the second groove with a first insulating layer, depositing a hard mask on the surface of the structure obtained in step S107, forming a third groove penetrating each patterned conductive layer by etching the hard mask with photolithography, and etching the first insulating layer and the patterned conductive layer which are distributed by stacking, wherein the third groove extends toward the substrate 1 and along the first direction, and the third groove exposes an end face of the first insulating layer, and the third groove may be formed at a location of the second groove;
2) laterally etching the first insulating layer on two sides of the third groove until the side surface of the exposed electrode 51 of a set depth is exposed, with the set depth being the length of the third electrode of the capacitor, that is, the exposed part is the third electrode region of the electrode 51;
3) sequentially depositing a dielectric layer and a conductive thin film covering the third electrode in the third groove to obtain the dielectric layer and the fourth electrode of the capacitor respectively. The third groove may be filled with the conductive thin film so that the fourth electrode is present at the location of each transistor connected to the two adjacent bit lines. In an exemplary embodiment of the present disclosure, the dielectric thin film and the conductive material may be deposited by Atomic Layer Deposition (ALD).

In an exemplary embodiment of the present disclosure, the dielectric layer may be formed by a High-K dielectric material, i.e., a dielectric material with a dielectric constant K≥3.9. The High-K dielectric material may include, but is not limited to, at least one of the following: silicon oxide, aluminum oxide (Al₂O₃), hafnium oxide, and the like.

In an exemplary embodiment of the present disclosure, the material of the conductive thin film includes, but is not limited to, at least one of the following: polysilicon, tungsten, and titanium nitride.

In an exemplary embodiment of the present disclosure, TiN or the like may be deposited as an oxidation prevention layer on the surface of the third electrode before the dielectric layer is deposited, so as to prevent the tungsten metal forming the third electrode from being oxidized by the oxygen-containing dielectric layer such as silicon oxide. Evidently, the dielectric layer may be an oxygen-free film layer, so an oxidation prevention layer does not need to be added to the conductive film.

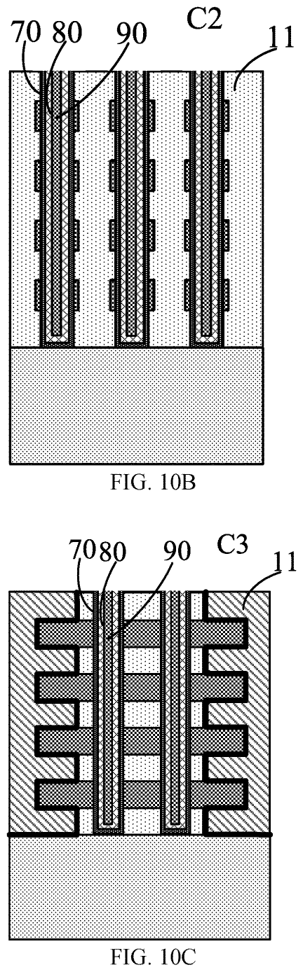

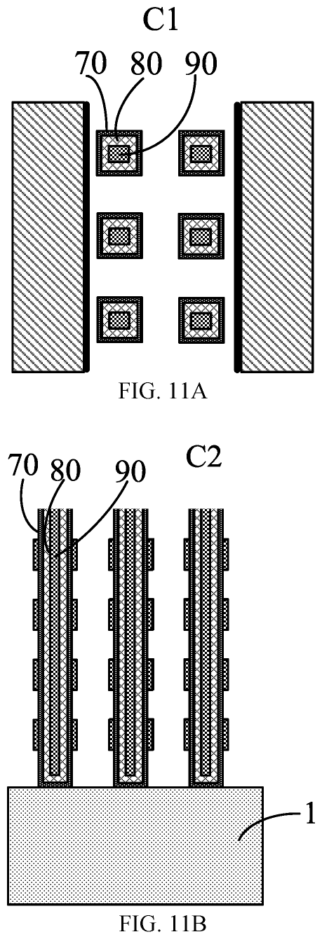

S109: removing the second insulating layer in the through hole by etching, sequentially depositing a semiconductor layer 70 and a gate insulating layer 80 on the inner wall of the through hole, filling the through hole with a gate electrode layer, and planarizing the semiconductor layer 70, the gate insulating layer 80, and the gate electrode layer on the top surface of the substrate by a CMP process, as shown in FIGS. 10A, 10B, and 10C. Here, FIG. 10A is a cross-sectional view on a C1 plane parallel to the substrate, and the C1 plane does not pass through the patterned conductive layer. FIG. 10B is a cross-sectional view on a C2 plane perpendicular to the substrate, and the C2 plane passes through the through hole and the first groove. FIG. 10C is a cross-sectional view on a C3 plane perpendicular to the substrate, and the C3 plane passes through the electrode.

In an exemplary embodiment of the present disclosure, the semiconductor layer includes any one or more of: Indium gallium zinc oxide (InGaZnO), indium zinc oxide (InZnO), indium gallium oxide (InGaO), indium tin oxide (InSnO), indium gallium tin oxide (InGaSnO), indium gallium zinc tin oxide (InGaZnSnO), indium oxide (InO), tin oxide (SnO), zinc tin oxide (ZnSnO, ZTO), indium aluminum zinc gold oxide (InAlZnO), zinc oxide (ZnO), indium gallium silicon oxide (InGaSiO), indium tungsten oxide (InWO, IWO), titanium oxide (TiO), nitrogen oxide Materials such as zinc oxide (ZnON), magnesium zinc oxide (MgZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), aluminum zinc tin oxide (AlZnSnO), gallium zinc tin oxide (GaZnSnO), zirconium zinc tin oxide (ZrZnSnO), etc., as long as the leakage current of the transistor can meet the requirements, the specific adjustment can be made according to actual situations.

These materials have a wide band gap and a low leakage current. For example, when the metal oxide material is IGZO, the leakage current of the transistor is small, thereby improving working performance of the dynamic memory.

The material of the metal oxide semiconductor layer or channel only emphasizes the element type of the material, and does not emphasize the atomic proportion in the material and the thin film quality of the material.

In an exemplary embodiment of the present disclosure, the gate insulating layer may be silicon oxide or a High-K dielectric material. In some embodiments, oxides of one or more of hafnium, aluminum, lanthanum, zirconium, etc. may be included, examples may include, for example, but are not limited to, at least one of the following: high K materials such as hafnium oxide (HfO₂), aluminum oxide (Al₂O₃), hafnium aluminum oxide (HfAlO), hafnium lanthanum oxide (HfLaO), zirconium oxide (ZrO₂), and the like.

In an exemplary embodiment of the present disclosure, the gate insulating layer may be deposited by ALD.

In an exemplary embodiment of the present disclosure, a material of the gate electrode layer may be any one or more of the following different types of materials:

a material of the gate electrode layer may be, for example, a metal such as tungsten, aluminum, titanium, copper, nickel, platinum, ruthenium, molybdenum, gold, iridium, rhodium, tantalum, cobalt and the like, or a metal alloy containing metals of these metals mentioned above.

Optionally, a material of the gate electrode layer may be a metal oxide, a metal nitride, a metal silicide, a metal carbide, etc., such as tin-doped indium oxide (ITO), indium-doped zinc oxide (IZO), indium oxide (InO), aluminum-doped zinc oxide (AZO), iridium oxide (IrOx), ruthenium oxide (RuOx) and other metal oxide conductive materials; for example, titanium nitride (TiN), tantalum nitride (TaN), tungsten nitride (WN), titanium aluminum nitride (TiAlN) and other metal nitride materials.

Evidently, a material of the gate electrode layer may also be a polysilicon material, or may also be a semiconductor material doped with a conductive material, such as silicon doped with conductive material, germanium doped with conductive material, silicon germanium doped with conductive material, or the like, or may be another material that embodies conductivity.

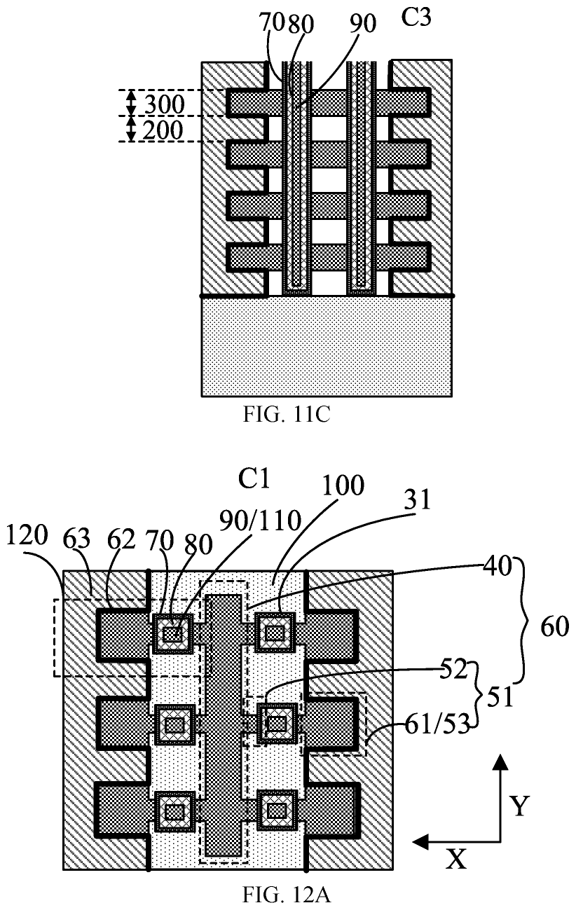

S110: removing all of the first insulating layers 11 by etching to expose the semiconductor layer 70 located in the parasitic MOS region 200 originally surrounded by the first insulating layers 11 and the first electrode region and the second electrode region of the exposed electrode 50, as shown in FIGS. 11A, 11B, and 11C. Here, FIG. 11A is a cross-sectional view on a C1 plane parallel to the substrate, and the C1 plane does not pass through the patterned conductive layer. FIG. 11B is a cross-sectional view on a C2 plane perpendicular to the substrate, and the C2 plane does not pass through the bit lines. FIG. 11C is a cross-sectional view on a C3 plane perpendicular to the substrate, and the C3 plane passes through the electrode.

S111: removing the semiconductor layer 70 located in the parasitic MOS region 200 by etching, retaining the semiconductor layer 70 located in the channel region 300, with the gate electrode layer surrounded by the semiconductor layer 70 being used as the gate electrode 90;

S112: removing the conductive layer on the opposite side walls of the semiconductor layer 70 by etching to separate the first electrode region and the second electrode region to disconnect the electrical connection between the first electrode region and the second electrode region, the separated first electrode region and the second electrode region serve as the first electrode 52 and the second electrode 53 respectively, the first electrode 52, the second electrode 53, the semiconductor layer 70, the gate insulating layer 80, and the gate electrode 90 constitute transistors, and the plurality of semiconductor layers 70 of the plurality of transistors are provided at intervals;

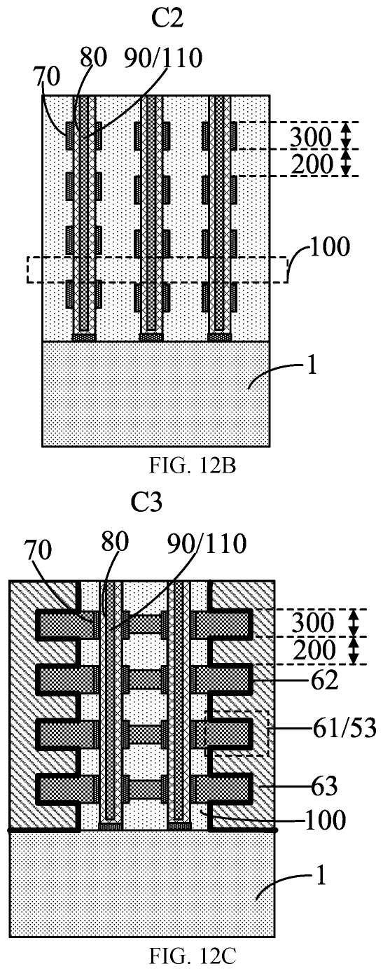

an insulating material is filled between two adjacent layers to form a third insulating layer 100 that isolates memory cells of different layers to obtain a semiconductor device as shown in FIGS. 12A, 12B, and 12C. Here, FIG. 12A is a cross-sectional view on a C1 plane parallel to the substrate, and the C1 plane passes through the patterned conductive layer. FIG. 12B is a cross-sectional view on a C2 plane perpendicular to the substrate, and the C2 plane does not pass through the bit lines. FIG. 12C is a cross-sectional view on a C3 plane perpendicular to the substrate, and the C3 plane passes through the gate electrode.

In an exemplary embodiment of the present disclosure, a material of the third insulating layer may be a low-K material, that is, a material with a dielectric constant K<3.9, for example, silicon dioxide (SiO₂) or the like, and forming the insulating layer using the low-K material may reduce parasitic capacitors between two adjacent transistors distributed in the direction perpendicular to the substrate.

In an exemplary embodiment of the present disclosure, the manufacturing method of the 3D stacked semiconductor device may further include connecting gate electrodes 90 of a column of transistors located in different layers together to form a word line 110 that penetrates the different layers. The word line 110 may extend along the direction perpendicular to the substrate 1.

The embodiments of the present disclosure further provide a 3D stacked semiconductor device, which can be obtained by the manufacturing method of the 3D stacked semiconductor device as provided in the above embodiment of the present disclosure.

As shown in FIGS. 12A, 12B, and 12C, a 3D stacked semiconductor device according to an embodiment of the present disclosure includes:

a plurality of memory cells 120 distributed in different layers, stacked along a direction perpendicular to the substrate 1 and periodically distributed, each layer including a plurality of columns of memory cells 120, the memory cells 120 including transistors;

a transistor includes a first electrode 52, a second electrode 53, a gate electrode 90, a semiconductor layer 70 surrounding a side wall of the gate electrode 90, and a gate insulating layer 80 disposed between the side wall of the gate electrode 90 and the semiconductor layer 70, the semiconductor layer 70 is connected to the first electrode 52 and the second electrode 53, and the gate electrode 90 extends in the direction perpendicular to the substrate 1.

In an exemplary embodiment of the present disclosure, as shown in FIGS. 12A, 12B, and 12C, the 3D stacked semiconductor device may further include:

a third insulating layer 100 and a conductive layer 60 alternately distributed sequentially from bottom to top along the direction perpendicular to the substrate. The conductive layer 60 includes a plurality of bit lines 40 extending in a first direction parallel to the substrate, and a plurality of electrodes 51 distributed on two sides of the bit lines 40 and connected to the bit lines 40. The electrodes 51 include a first electrode 52 and a second electrode 53.

Among them, the conductive layer 60 is obtained by replacing and patterning a sacrificial layer in a stacked structure formed by alternately stacking a first insulating layer and a sacrificial layer.

In an exemplary embodiment of the present disclosure, as shown in FIGS. 12A, 12B, and 12C, transistors of two columns of memory cells located on a same layer and adjacent to each other in a second direction parallel to the substrate 1 are connected to the same bit line 40.

In an exemplary embodiment of the present disclosure, as shown in FIGS. 12A, 12B, and 12C, the memory cell may further include a capacitor;

the capacitor includes a third electrode 61 located on the conductive layer 60. The third electrodes 61 of the capacitors of the plurality of memory cells 120 stacked and distributed extend in the second direction. The topography of cross sections of the third electrodes 61 of the different capacitors at a same position (i.e. the cross sections perpendicular to the substrate 1 and perpendicular to the extension direction of the third electrodes) is the same, the cross sections of the third electrode 61 at different positions gradually increase along a direction close to the transistor, for example, a width of a cross section of a third electrode 61 parallel to the substrate gradually increases along the direction close to the transistor.

As shown in FIGS. 12A and 12C, the capacitor further includes a fourth electrode 63, and a dielectric layer 62 disposed between the third electrode 61 and the fourth electrode 63, and the fourth electrode 63 and the dielectric layer 62 surround an end face and a sidewall of the third electrode 61.

As shown in FIGS. 12A and 12C, the 3D stacked semiconductor device further includes a word line 110, and the word line 110 penetrates the different layers and extends along a direction perpendicular to the substrate 1. The gate electrode 90 of each transistor is a part of the word line 110, and a plurality of semiconductor layers 70 of the plurality of transistors are arranged at intervals, and the plurality of semiconductor layers 70 are distributed in different regions of the sidewall of the word line 110.

In the 3D stacked semiconductor device according to the embodiment of the present disclosure a horizontal structure capacitor is employed, the capacitor is disposed on the transistor side to construct a memory cell of 1T1C structure, and a plurality of memory cells are stacked together along the direction perpendicular to the substrate to form a 3D stacked device, which can improve a memory density of the semiconductor device.

In addition, the semiconductor layer spacing of transistors in at least part of adjacent layers of the 3D stacked semiconductor device provided by the embodiment of the present disclosure can reduce or eliminate parasitic MOS transistors (referred to as parasitic MOS for short) between at least part of the layers, and improve device stability.

In an exemplary embodiment of the present disclosure, the semiconductor layers of the transistors of different layers are disposed at intervals in the direction perpendicular to the substrate, that is, the semiconductor layers of the transistors of all adjacent layers are disposed at intervals in the direction perpendicular to the substrate, so that parasitic MOS between all adjacent layers can be eliminated and device stability can be improved.

In an exemplary embodiment of the present disclosure, as shown in FIGS. 12A, 12B, and 12C, the 3D stacked semiconductor device may further include:

a through hole 31 penetrating each of the third insulating layers 100 and each of the conductive layers 60, wherein in the through hole 31, the word line 110, the gate insulating layer 80 surrounding the sidewall of the word line 110, and a plurality of the semiconductor layers 70 surrounding different regions of the sidewall of the gate insulating layer 80 are distributed in order from the inside to the outside;

a plurality of semiconductor layers 70 extending in the direction perpendicular to the substrate 1 and disconnected at a sidewall of the third insulating layer 100;

The conductive layer 60 includes a plurality of electrodes 51, and an electrode 51 includes a first electrode region and a second electrode region spaced apart from each other. The first electrode region and the second electrode region form the first electrode 52 and the second electrode 53 of the transistor respectively, and each semiconductor layer 70 is in contact with a first electrode region and a second electrode region of a conductive layer 60 of a corresponding layer.

In an exemplary embodiment of the present disclosure, the through hole is formed by a single process.

In an exemplary embodiment of the present disclosure, the semiconductor layer is formed only at an end portion of the conductive layer, and does not extend to the upper and lower surfaces of the conductive layer.

In an exemplary embodiment of the present disclosure, the semiconductor layer extends only along a direction perpendicular to the substrate, and does not include a region extending along the first direction.

In an exemplary embodiment of the present disclosure, the first electrode 52 may be a source electrode, and the second electrode 53 may be a drain electrode. Optionally, the first electrode 52 may be a drain electrode and the second electrode 53 may be a source electrode.

In an exemplary embodiment of the present disclosure, as shown in FIG. 12A, the bit line 40 is connected to first electrodes 52 of two columns of transistors located on a same layer and adjacent to each other. The first electrodes 52 and bit lines 40 of the two columns of transistors located on a same layer and adjacent to each other may be of an integral structure.

In an exemplary embodiment of the present disclosure, the first electrode 52 of the transistor may be a part of the bit line 40 to which the first electrode 52 is connected.

In an exemplary embodiment of the present disclosure, as shown in FIGS. 12A, 12B, and 12C, the third electrode 61 of the capacitor is connected to the second electrode 53 of the transistor located on the same layer, and the third electrode 61 and the second electrode 53 may be of an integral structure, or share one electrode, or it may be understood as that the third electrode and the second electrode 53 refer to one electrode, in which a part of the region is connected to the semiconductor layer and a part of the region overlaps with the outer electrode of the capacitor.

In an exemplary embodiment of the present disclosure, as shown in FIG. 12A, the third electrode 61 and the fourth electrode 63 of the capacitor may be insulated by a dielectric layer 62.

In an exemplary embodiment of the present disclosure, as shown in FIG. 12C, fourth electrodes 63 of capacitors of a same column of different layers may be of an integral structure.

In an exemplary embodiment of the present disclosure, as shown in FIG. 12C, the dielectric layer 62 of the capacitors of a same column of different layers may be of an integral structure.

In an exemplary embodiment of the present disclosure, the semiconductor layer may extend on the sidewall of the gate electrode to form an annular semiconductor layer extending along the direction perpendicular to the substrate, including the semiconductor layer extending only in a direction perpendicular to the substrate, or the semiconductor layer extending on the body in a direction perpendicular to the substrate, and horizontal portions extending laterally and toward the gate electrode may be present at the end portions.

Herein, “surrounding” may be understood as partially or completely surrounding the gate electrode. In an exemplary embodiment of the present disclosure, the “surrounding” may be that the semiconductor layer entirely surrounds the gate electrode as a whole, that is, the cross section of the semiconductor layer is a closed ring shape, as shown in FIG. 12A. The cross section is taken along a direction parallel to the substrate. In an exemplary embodiment of the present disclosure, the “surrounding” may be partially “surrounding”, and the cross section after the “surrounding” is not closed, but presents a ring shape. For example, the ring shape may be a ring shape having an opening.

In an exemplary embodiment of the present disclosure, material compositions of the different areas of the word line extending in a direction perpendicular to the substrate may be identical, which may be understood as being formed using the same film layer fabrication process, and the material compositions being identical may be understood as major elements tested in the material being identical, for example, all formed by conductive materials such as metals, metal nitrides or metal oxides. For example, all are made of TI, TiN, W, ITO, IZO and other conductive materials.

In an exemplary embodiment of the present disclosure, as shown in FIGS. 12B and 12C, transistors stacked in different layers may share one word line 110 extending along the direction perpendicular to the substrate 1.

In an exemplary embodiment of the present disclosure, as shown in FIGS. 12B and 12C, semiconductor layers 70 corresponding to transistors of different layers may be located on the sidewall of the word lines 110 and are located in different regions extending in the direction perpendicular to the substrate 1 respectively.

In an exemplary embodiment of the present disclosure, as shown in FIGS. 12B and 12C, the gate electrodes 90 of transistors of different layers are parts of the word line 110, and the word line 110 is exposed between the semiconductor layers 70 disposed at intervals.

In the exemplary embodiment of the present disclosure, as shown in FIGS. 12B and 12C, an insulating layer is exposed between the semiconductor layers 70 provided at intervals, the insulating layer is a gate insulating layer 80 located between a gate electrode 90 and a semiconductor layer 70, and gate insulating layers 80 of transistors in the same column of different layers are of an integral structure. According to the scheme provided by the present embodiment, the first electrode 52 and the gate electrode 90 are isolated by the gate insulating layer 80, so that the first electrode 52 is avoided from being exposed due to overetching, so that a short circuit between the first electrode 52 and the gate electrode 90 can be avoided.

In an exemplary embodiment of the present disclosure, transistors of different layers may share a ring-shaped gate insulating layer extending along the direction perpendicular to the substrate.

In an exemplary embodiment of the present disclosure, materials of the third insulating layer, the gate insulating layer, and the dielectric layer are the same, and which are all silicon oxide.

In an exemplary embodiment of the present disclosure, a cross section of the third electrode is larger than a cross section of the first electrode to which the bit line is connected. Making the capacitor electrode as large as possible can increase the capacitance.

In an exemplary embodiment of the present disclosure, gate insulating layers of transistors of at least part of adjacent layers may be disposed at intervals in the direction perpendicular to the substrate.

In an exemplary embodiment of the present disclosure, gate insulating layers of transistors of different layers are provided at intervals in the direction perpendicular to the substrate.

In an exemplary embodiment of the present disclosure, a channel between the first electrode and the second electrode of one of the transistors may be a horizontal channel.

Horizontal channel means that a transport direction of carriers in the channel is in a plane parallel to the substrate, but it is not limited that the transport direction of the carriers must be one direction. In practical applications, the transport direction of the carriers extends in one direction as a whole, but locally, it is related to a shape of the semiconductor layer. In other words, the horizontal channel does not mean that it must extend along one direction in the horizontal plane, but may extend along different directions. For example, when the semiconductor layer is annular, the source contact region and the drain contact region on the annular semiconductor layer are a portion of the annulus, and in this case, carriers extend along one direction from the source contact region to the drain contact region as a whole, but may not be in one direction locally. Evidently, the transport direction of the carriers in a plane parallel to the substrate is also a macroscopic concept, and is not limited to being absolutely parallel to the substrate. The present application protects the channel between the first electrode and the second electrode as a channel not perpendicular to the substrate.

In an exemplary embodiment of the present disclosure, transistors of a same layer may be distributed in an array along a second direction and a first direction, and the first electrode 52 and the second electrode 53 of the transistors may extend along the second direction, and the first direction may be perpendicular to the second direction. The second direction may be shown as X in FIG. 12A, and the first direction may be shown as Y in FIG. 12A.

In an exemplary embodiment of the present disclosure, as shown in FIG. 12A, the bit line 40 may extend in the first direction, such as the Y direction.

In an exemplary embodiment of the present disclosure, the 3D stacked semiconductor device may be a 3D memory, such as a 3D DRAM memory or the like. The 3D memory may have a 1T1C structure.

Embodiments of the present disclosure further provide an electronic equipment including the 3D stacked semiconductor device as provided by the above embodiments of the present disclosure.

In exemplary embodiments of the present disclosure, the electronic equipment may be a storage apparatus, a smart phone, a computer, a tablet computer, an artificial intelligence device, a wearable device, a mobile power supply, or the like. The storage apparatus may include a memory in a computer or the like, which is not limited here.

Although implementations disclosed in the present disclosure are as described above, the described contents are only implementations used for facilitating understanding of the present disclosure, but are not intended to limit the present disclosure. Without departing from the spirit and scope disclosed in the present disclosure, any person skilled in the art to which the present disclosure belongs may make any modifications and changes in the implementation form and details, however the protection scope of the present disclosure shall still be defined by the appended claims.

1. A manufacturing method of a 3D stacked semiconductor device, wherein the 3D stacked semiconductor device comprises: a word line, bit lines, and different layers of memory cells stacked and distributed in a direction perpendicular to a substrate, wherein each layer comprises a plurality of columns of memory cells, each memory cell comprises a transistor, the word line penetrates through the different layers of memory cells, and the bit lines extend along a first direction parallel to the substrate;
the manufacturing method comprises:
alternately depositing a first insulating layer and a sacrificial layer on the substrate sequentially to obtain a stacked structure;
etching the stacked structure, forming a plurality of through holes extending toward the substrate in the stacked structure, and depositing a second insulating layer within the through holes;
performing patterned etching on the stacked structure with the through holes to obtain a patterned sacrificial layer comprising a plurality of bit line regions and a plurality of electrode regions distributed between any two adjacent bit line regions; and
replacing the patterned sacrificial layer with a conductive layer comprising a plurality of bit lines extending along the first direction and a plurality of electrodes distributed on two sides of the bit lines and connected to the bit lines.

2. The manufacturing method of claim 1, wherein the performing patterned etching on the stacked structure with the through holes to obtain the patterned sacrificial layer comprises:
performing patterned etching on the stacked structure with the through holes to form a plurality of first grooves extending toward the substrate in the stacked structure, wherein the first grooves extend in a second direction parallel to the substrate and are located between two adjacent through holes distributed in the first direction, to obtain the patterned sacrificial layer.

3. The manufacturing method of claim 2, wherein the performing patterned etching on the stacked structure with the through holes to obtain the patterned sacrificial layer further comprises:
performing patterned etching on the stacked structure with the through holes, to form a plurality of second grooves extending toward the substrate in the stacked structure, wherein the second grooves extend along the first direction and are located between any two adjacent bit line regions to obtain an electrode region having only one end connected to a bit line region through a transistor.

4. The manufacturing method of claim 2, wherein the replacing the patterned sacrificial layer with the conductive layer comprises:
removing all of patterned sacrificial layers between first insulating layers by etching;
filling the conductive layer between a first groove and two adjacent first insulating layers; and
removing the conductive layer in the first groove by etching to obtain a patterned conductive layer, and replacing the patterned sacrificial layer with the patterned conductive layer.

5. The manufacturing method of claim 3, wherein the memory cell further comprises a capacitor comprising a third electrode, a fourth electrode, and a dielectric layer disposed between the third electrode and the fourth electrode;
the manufacturing method further comprises, after replacing the patterned sacrificial layer with the conductive layer, performing following steps of:
laterally etching first insulating layers on two sides of the second groove until side surfaces of a set depth of the electrode are exposed, with the set depth being a length of the third electrode of the capacitor; and
forming the dielectric layer and the fourth electrode of the capacitor sequentially in an exposed region of the electrode.

6. The manufacturing method of claim 5, further comprising, before or after forming the capacitor, performing following steps of:
removing the second insulating layer in a through hole by etching, and sequentially depositing a semiconductor layer and a gate insulating layer on an inner wall of the through hole, and filling the through hole with a gate electrode layer;
removing the first insulating layer by etching to expose a semiconductor layer in a parasitic Metal-Oxide-Semiconductor (MOS) region originally surrounded by the first insulating layer; and
removing the semiconductor layer located in the parasitic MOS region by etching, with a gate electrode layer surrounded by a semiconductor layer located in a channel region being used as a gate electrode, and gate electrodes of transistors of a column of memory cells located in different layers being connected to form the word line.

7. The manufacturing method of claim 6, further comprising, after obtaining the gate electrode, performing following steps of:
removing a conductive layer on opposite sidewalls of the semiconductor layer by etching such that an end of the electrode close to the bit line is spaced apart as a first electrode and a second electrode.

8. The manufacturing method of claim 1, wherein the sacrificial layer does not contain a metallic element.

9. The manufacturing method of claim 8, wherein both the first insulating layer and the sacrificial layer contain a silicon element.

10. The manufacturing method of claim 9, wherein a material of the first insulating layer is silicon oxide, and a material of the sacrificial layer is silicon nitride or polysilicon.

11. A 3D stacked semiconductor device, comprising:
a plurality of memory cells distributed in different layers stacked along a direction perpendicular to a substrate and periodically distributed; wherein each layer comprises a plurality of columns of memory cells, and a memory cell comprises a transistor; the transistor comprises a first electrode, a second electrode, a gate electrode, a semiconductor layer surrounding a sidewall of the gate electrode, and a gate insulating layer disposed between the sidewall of the gate electrode and the semiconductor layer, the semiconductor layer connects the first electrode with the second electrode; and the gate electrode extend along a direction perpendicular to the substrate;
a plurality of bit lines extending along a first direction parallel to the substrate, and transistors of two columns of memory cells located on a same layer and adjacent in a second direction parallel to the substrate connected to a same bit line;
wherein the bit line located on a same layer is located on a same conductive layer as the first electrode and the second electrode of the transistor; and
the conductive layer is obtained by replacing and patterning a sacrificial layer in a stacked structure formed by alternately stacking a first insulating layer and a sacrificial layer.

12. The 3D stacked semiconductor device of claim 11, further comprising a word line extending along the direction perpendicular to the substrate, a third insulating layer positioned between two adjacent conductive layers, the word line being positioned in a through hole penetrating various third insulating layers and various conductive layers;
wherein the through hole is formed by a single process.

13. The 3D stacked semiconductor device of claim 12, wherein the semiconductor layer is formed only at an end portion of the conductive layer and does not extend to upper and lower surfaces of the conductive layer.

14. The 3D stacked semiconductor device of claim 12 wherein the semiconductor layer extends only along the direction perpendicular to the substrate and does not comprise a region extending along the first direction.

15. The 3D stacked semiconductor device of claim 12, wherein the memory cell further comprises a capacitor connected to the transistor;
the capacitor comprises a third electrode on the conductive layer, wherein third electrodes of capacitors of the plurality of memory cells distributed by stacking extend in the second direction; cross-sectional shapes of the third electrodes at a same position are the same, and cross sections of the third electrodes at different positions gradually increase along a direction close to the transistor.

16. The 3D stacked semiconductor device of claim 15, wherein the capacitor further comprises a fourth electrode and a dielectric layer disposed between the third electrode and the fourth electrode;
wherein the third insulating layer, the gate insulating layer, and the dielectric layer are made of a same material and are all made of silicon oxide.

17. The 3D stacked semiconductor device of claim 15, wherein a cross section of the third electrode is larger than a cross section of the first electrode to which the bit line is connected.

18. The 3D stacked semiconductor device of claim 12, wherein a plurality of semiconductor layers extend along the direction perpendicular to the substrate and are disconnected at a sidewall of the third insulating layer.

19. The 3D stacked semiconductor device of claim 12, wherein the bit lines are connected to first electrodes of two columns of transistors which are located on a same layer and adjacent to each other; the first electrodes of the two columns of transistors which are located on a same layer and adjacent to each other and the bit line are of an integral structure.

20. An electronic equipment comprising the 3D stacked semiconductor device of claim 11.
